(19) United States
(12) Patent Application Publication
(10) Pub. No.: US 2019/0198719 A1
(43) Pub. Date: Jun. 27, 2019

(54) LIGHT EMITTING DEVICE, LIGHT SOURCE DEVICE, AND DISPLAY DEVICE

(71) Applicant: NICHIA CORPORATION, Anan-shi (JP)

(72) Inventors: Akihiro FUJIOKA, Tokushima-shi (JP); Seitaro AKAGAWA, Komatsushima-shi (JP)

(21) Appl. No.: 16/226,115

(22) Filed: Dec. 19, 2018

(30) Foreign Application Priority Data
Dec. 21, 2017 (JP) 2017-245041

(51) Int. Cl. H01L 33/50; H01L 25/075; H01L 33/48; H01L 33/56; H01L 33/60; H01L 33/62; H01L 33/64; C09K 11/77; C09K 11/08

(52) U.S. Cl. CPC H01L 33/502; H01L 25/0753; H01L 33/486; H01L 33/56; C09K 11/0883; H01L 33/62; H01L 33/647; C09K 11/7734; H01L 33/60

(57) ABSTRACT

A light emitting device includes a first light emitting element and a first sealing member. The first light emitting element has a peak emission wavelength of 430 nm or greater and less than 490 nm. The first sealing member covers the first light emitting element, and contains a first phosphor having a peak emission wavelength of 490 nm or greater and 570 nm or less. A content of the first phosphor is 50 weight % or greater with respect to the total weight of the first sealing member. A mixed color light in which light emitted from the first light emitting element and light emitted from the first phosphor are mixed has an excitation purity of 70% or greater on a 1931 CIE chromaticity diagram.

### CROSS-REFERENCE TO RELATED APPLICATIONS

This application claims priority to Japanese Patent Application No. 2017-245041 filed on Dec. 21, 2017. The entire disclosure of Japanese Patent Application No. 2017-245041 is hereby incorporated herein by reference.

### TECHNICAL FIELD

The present disclosure relates to a light emitting device, a light source device, and a display device.

### BACKGROUND ART

In Japanese Unexamined Patent Publication No. 2011-140664, a light source device comprising a blue light emitting device, a green light emitting device, and a red light emitting device is described. A liquid crystal display device or the like using such a light source device can exhibit a high color reproducibility.

### SUMMARY

Liquid crystal display devices and the like are sometimes required to have desired color reproductivity and light output according to use. Accordingly, various light emitting devices used for light source devices for liquid crystal display devices are also required to have such a color reproductivity and a light output.

In view of the above, one object of certain embodiments of the present invention is to provide a light emitting device or the like with which a liquid crystal display can have desired color reproducibility and light output.

A light emitting device according to certain embodiments of the present invention includes a first light emitting element and a first sealing member. The first light emitting element has a peak emission wavelength of 430 nm or greater and less than 490 nm. The first sealing member covers the first light emitting element, and contains a first phosphor having a peak emission wavelength of 490 nm or greater and 570 nm or less. A content of the first phosphor is 50 weight % or greater with respect to the total weight of the first sealing member. A mixed color light in which light emitted from the first light emitting element and light emitted from the first phosphor are mixed has an excitation purity of 70% or greater on a 1931 CIE chromaticity diagram.

According to certain embodiments of the present invention, it is possible to provide a light emitting device with which a liquid crystal display or the like having a desired color reproducibility or light output can be provided.

### DESCRIPTION OF THE DRAWINGS

FIG. 1A is a schematic top view of a light emitting device according to an embodiment.

FIG. 1B is a schematic cross-sectional view of a line 1B-1B in FIG. 1A.

FIG. 2 is a drawing showing the light emission spectrum of the light emitting device.

FIG. 3 is a drawing showing the chromaticity of the light emitting device on the 1931 CIE chromaticity diagram.

FIG. 4A is a schematic top view of the light emitting device according to an embodiment.

FIG. 4B is a schematic cross-sectional view taken along line 4B-4B in FIG. 4A.

FIG. 5A is a schematic top view of the light emitting device according to an embodiment.

FIG. 5B is a schematic cross-sectional view of line 5B-5B in FIG. 5A.

FIG. 6 is a drawing showing the light emission spectrum of the light emitting device.

FIG. 7 is a schematic exploded perspective view of the display device of an embodiment.

FIG. 8A is a schematic top view showing a lead part.

FIG. 8B is a schematic top view of a package.

FIG. 8C is a schematic top view of the light emitting device.

FIG. 9A is a schematic top view showing an example of the light emitting device.

FIG. 9B is a schematic cross sectional view taken along a line 9B-9B in FIG. 9A.

### DETAILED DESCRIPTION OF EMBODIMENTS

A detailed explanation is given below based on the drawings. Parts with the same reference numeral represented in a plurality of drawings show parts or members that are the same or similar.

Furthermore, the description below is an example of the light emitting device to give a concrete form to the technical concept of the present invention, and the present invention is not limited to the description below. Unless specifically noted, descriptions on dimensions, materials, shapes and relative arrangements, etc., of components are not intended to limit the scope of the present invention thereto, but are given for exemplification. Also, in the description below, expressions that indicate a specific direction or position (e.g. “up,” “down,” and other terms that include those terms) may be used. Those expressions are used for ease of understanding of relative direction or position in the referenced drawings. The size or positional relationship, etc., of members shown by each drawing may be exaggerated to facilitate understanding, etc. The relationship of color names and chromaticity coordinates, the relationship of the light wavelength range and the color name of a monochromatic light, etc., are in compliance with JIS Z8110.

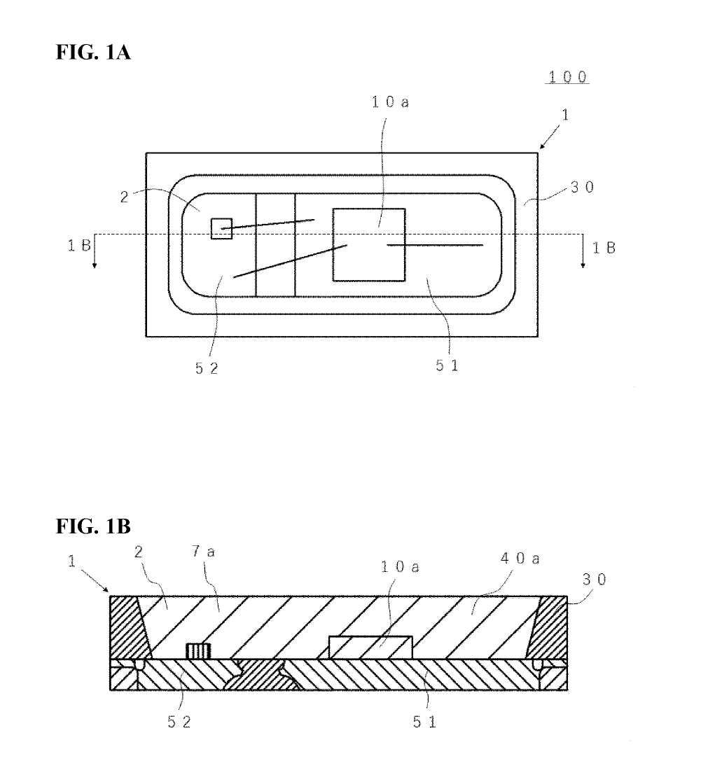

FIG. 1A is a schematic top view of a light emitting device 100 according to one embodiment, and FIG. 1B is a schematic bottom view of the light emitting device 100. In FIG. 1A, illustrations of a first phosphor 7a and a first sealing member 40a are omitted. The light emitting device 100 comprises a first light emitting element 10a having a peak emission wavelength of 430 nm or greater and less than 490 nm, and a first sealing member 40a that covers the first light emitting element 10a and that contains the first phosphor 7a having a peak emission wavelength of 490 nm or greater and 570 nm or less. The light emitting device 100 shown in FIG. 1A further comprises a package 1 that comprises a recess 2.

The light emitting device 100 comprises the first light emitting element 10a having the peak emission wavelength of 430 nm or greater and less than 490 nm. The first light emitting element 10a emits blue light. With the first light emitting element 10a having a peak emission wavelength of a longer wavelength than the near ultraviolet region, it is possible to reduce disadvantages of light in the near ultraviolet region (e.g. having an adverse effect on a human body or an irradiated object, causing degradation of the constituent members of the light emitting device, and a great decrease in the light emitting efficiency of the light emitting device).

The light emitting device 100 shown in FIG. 1A includes a single first light emitting element 10a disposed on the bottom surface of the recess 2. The first light emitting element 10a has a rectangular outline shape in the top view. In the light emitting device 100, it is possible to change the number of or the shape of the outline of the first light emitting elements 10a according to the purpose or application.

The first light emitting element 10a preferably has a height sufficiently smaller than the depth of the recess 2. For example, the height of the first light emitting element 10a is 0.5 times or less than a depth of the recess 2, preferably 0.4 times or less, and more preferably 0.37 times or less. The height of the first light emitting element 10a, for example, is 250 μm or less, and preferably 150 μm. Also, the depth of the recess 2 is preferably ⅔ or greater of the height of the package 1. With this arrangement, inside the recess 2, it is possible to increase the volume of the first sealing member 40a containing the phosphor 7a (green phosphor described later) placed in the recess 2, and thus is possible to increase the content of the first phosphor 7a. Thus, light emitted by the light emitting device 100 can have an excitation purity for the green light described below.

The light emitting device 100 comprises the first sealing member 40a that contains the first phosphor 7a having the peak emission wavelength in the range of 490 nm to 570 nm. The first sealing member 40a covers the first light emitting element 10a. In the light emitting device 100 shown in FIG. 1B, the first sealing member 40a includes a resin material such as silicone resin and the first phosphor 7a contained in the resin material. The first sealing member 40a is, for example, formed by hung placed inside the recess 2 using a potting technique, etc., and being solidified.

The first phosphor 7a is a green phosphor adapted to absorb blue light emitted by the first light emitting element 10a, and to emit green light. For the first phosphor 7a, it is preferable to use a (Ca, Sr, Ba)₈MgSi₄O₁₆ (F, Cl, Br)₂:Eu phosphor, and particularly preferable to use a Ca₈MgSi₄O₁₆Cl₂:Eu phosphor. The Ca₈MgSi₄O₁₆Cl₂:Eu phosphor has high absorption efficiency with respect to light emitted from the first light emitting element 10a, and thus allows for easily reducing the blue component and increasing the green component in light emitted from the light emitting device 100. Also, the Ca₈MgSi₄O₁₆Cl₂:Eu phosphor has a half band width in the light emission spectrum of 65 nm or less, with which the color reproducibility of a display device can be improved when the light emitting device 100 is incorporated in the display device as the light source.

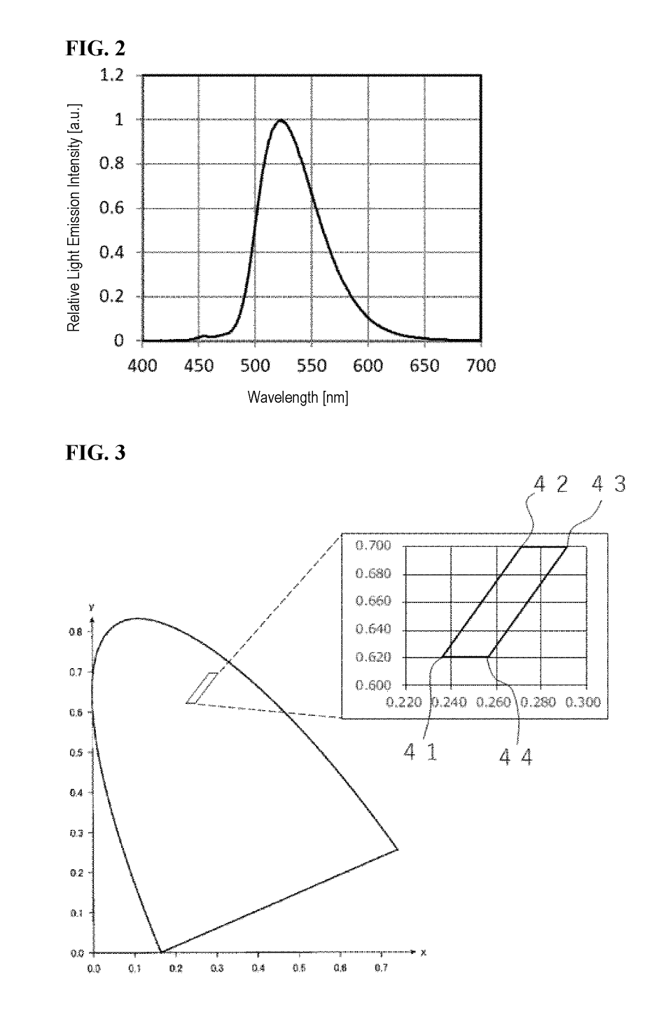

The content of the first phosphor 7a in the first sealing member 40a is 50 weight % or greater with respect to the total weight of the first sealing member 40a. With the first phosphor 7a contained at 50 weight % or greater in the first sealing member 40a, it is possible to increase the ratio of the green component to the blue component in the light emission spectrum of the light emitting device 100. FIG. 2 is a drawing showing the light emission spectrum of the light emitting device 100. The first light emitting element 10a and the first phosphor 7a are configured to have desired peak emission wavelengths such that, in the light emission spectrum of the light emitting device 100 shown in FIG. 2, the emission intensity at the peak emission wavelength of the first light emitting element 10a is 0.1 times or less of the emission intensity at the peak emission wavelength of the first phosphor 7a. More preferably, the first light emitting element 10a and the first phosphor 7a, are configured so that, in the light emission spectrum of the light emitting device 100 shown in FIG. 2, the peak emission intensity of the first light emitting element 10a is 0.01 times or more and 0.03 times or less of the peak emission intensity of the first phosphor 7a. With this arrangement, the light emitting device 100 can be a green-light emitting device in which the first light emitting element 10a configured to emit blue light serves as a light source.

Typically, in the case of a nitride-based light emitting element in which the light emitting layer contains indium, an amount of indium added in a green light emitting element is greater than that in a blue light emitting element, so that the light output of the green light emitting element is lower than that of the blue light emitting element. However, in the light emitting device 100 of the present disclosure, the first light emitting element 10a, which is a blue light emitting element, and the first phosphor 7a, which has high excitation efficiency with respect to the emitted light of the first fight emitting element 10a, is used, which allows for realizing higher light output compared to the nitride-based green light emitting element.

Also, with the first sealing member 40a containing the first phosphor 7a at 50 weight % or greater, on the 1931 CIE chromaticity diagram, the excitation purity of the mixed color light of the light emitted from the first light emitting element 10a and the light emitted from the first phosphor 7a can be 70% or greater. As used herein, the “excitation purity” represents a saturation of an emission color. The excitation purity P is represented by formula (I) or formula (II) shown below, where, on the 1931 CIE chromaticity diagram, the coordinates of the white point (i.e., achromatic point) are represented by N (xₙ, yₙ), the chromaticity coordinates of light emitted from the light emitting device 100 (i.e., mixed color light) are represented by C (x_{c}, y_{c}), and the coordinates of the intersection point of a straight line extending from the coordinates N toward the coordinates C with the spectrum locus are D (x_{d}, y_{d}).

$$\begin{matrix}P = \frac{{x}_{c} - {x}_{n}}{{x}_{d} - {x}_{n}} \times 100 ( \% ) & ( I ) \\ P = \frac{{y}_{c} - {y}_{n}}{{y}_{d} - {y}_{n}} \times 100 ( \% ) & ( II )\end{matrix}$$

With the excitation purity P to the green light being 70% or greater, a display device in which the light emitting device 100 serving as the light source is incorporated, the color reproducibility in the green region can be improved. The excitation purity P is, for example, preferably 75% or greater, and more preferably 78% or greater.

The content of the first phosphor 7a in the first sealing member 40a is, for example, preferably 75 weight % or less with respect to the total weight of the first sealing member 40a, and more preferably 60 weight % or less. With such a content, as shown in the light emission spectrum of the light emitting device 100 shown in FIG. 2, the light emitting device 100 can have a small spike in the blue region. Accordingly, a portion of blue light emitted from the first light emitting element 10a with high light intensity is emitted to outside, so that it is possible to improve light emission intensity of the light emitting device 100. Thus, while increasing the excitation purity of the green light of the light emitting device 100, it is possible to have a light emitting device with even higher light emission intensity.

In addition to the first phosphor 7a, the first sealing member 40a preferably further contains a diffusion member such as SiO₂ with a small grain shape. With this arrangement, when manufacturing a plurality of light emitting devices, it is possible to reduce manufacturing variation in chromaticity between the plurality of light emitting devices. For example, among a plurality of light emitting devices, when the first sealing member 40a is disposed using potting, in a light emitting device in which potting was performed the first of the plurality of light emitting devices, the first phosphor 7a contained in the first sealing member 40a may be precipitated more downward compared to the light emitting device in which the potting was performed the last of the plurality of light emitting devices. With this arrangement, the chromaticity of the light emitting device in which the potting was performed the first of the plurality of light emitting devices and the chromaticity of the light emitting device in which the potting vas performed at the last of the plurality of light emitting devices may be different from each other. Meanwhile, a diffusion member such as SiO₂ with a small grain shape, serves to reduce precipitation of the phosphor particles in the scaling member, so that it is possible to effectively reduce variation in chromaticity among a plurality of light emitting devices. The grain shape of the diffusion member is, for example, 100 nm or less, and preferably 55 nm or less. Unless otherwise noted, in this specification, a particle diameter of a diffusion member, a light scattering particle, or the like, refers to a value determined as a Fisher Number measured by using Fisher-SubSieve-Sizer (F.S.S.S.) that employs an air permeable method.

As shown in FIG. 3, the chromaticity of the light emitting device 100, for example, on the 1931 CIE chromaticity diagram, is positioned in a region surrounded by a first point 41, a second point 42, a third point 43, and a fourth point 44. The x, y coordinates of the first point 41 are 0.236, 0.620; the x, y coordinates of the second point 42 are 0.272, 0.700; the y coordinates of the third point 43 are 0.292, 0.700; and the x, y coordinates of the fourth point 44, are 0.256, 0.620.

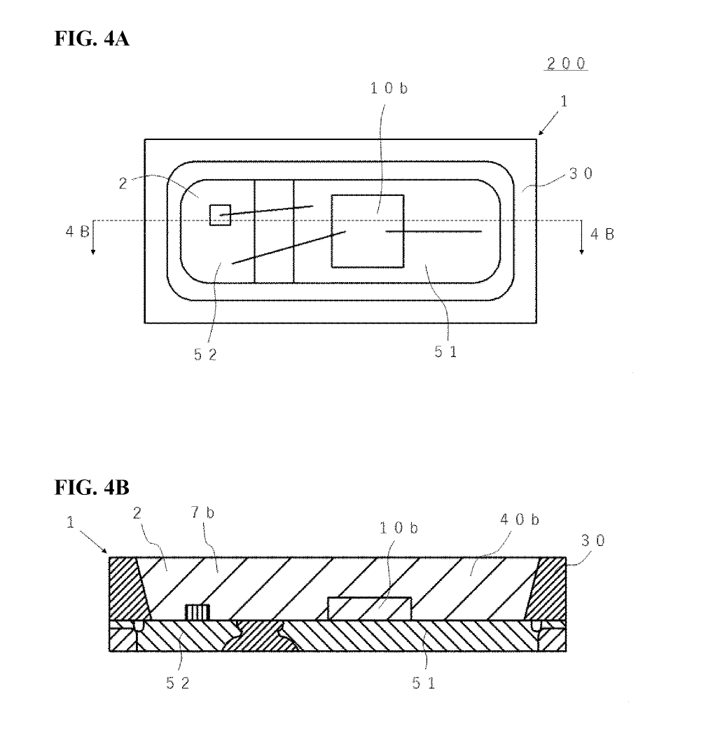

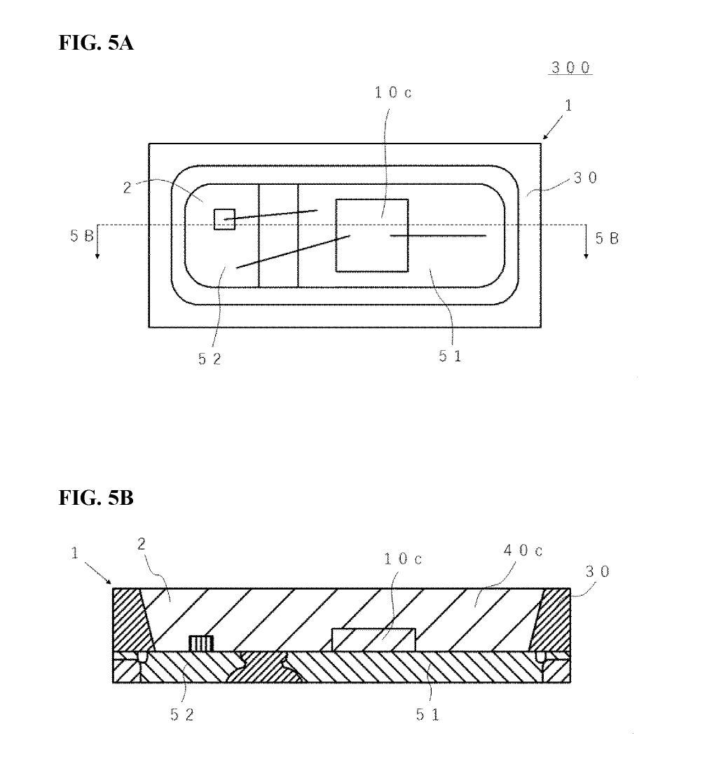

Next, a light emitting device 200 configured to emit red light, and a light emitting device 300 configured to emit blue light will be described. FIG. 4A is a schematic top view of the light emitting device 200 according to another embodiment, and FIG. 4B is a schematic cross-sectional view taken along a line 4B-4B in FIG. 4A. FIG. 5A is a schematic top view of the light emitting device 300 according to even another embodiment, and FIG. 5B is a schematic cross-sectional view taken along a line 5B-5B in FIG. 5A. With FIG. 4A and FIG. 5A, illustration of the phosphor, the sealing member, etc., are omitted. The light emitting device 200 comprises a second light emitting element 10b having the peak emission wavelength of 430 nm or greater and less than 490 nm, and a second sealing member 40b that covers the second light emitting element 10b and that contains a second phosphor 7b having the peak emission wavelength of 580 nm or greater and 680 nm or less. Also, the light emitting device 300 comprises a third light emitting element 10c having the peak emission wavelength of 430 nm or greater and less than 490 nm, and a third sealing member 40c that covers the third light emitting element 10c and that does not contain phosphor.

The light emitting device 200 and the light emitting device 300 shown in FIG. 4A and FIG. 5A comprise the package 1 having the recess 2 as in the light emitting device 100. Also, the second light emitting element 10b and the third light emitting element 10c, similarly to the first light emitting element 10a, are light emitting elements having the peak emission wavelength of 430 nm or greater and less than 490 nm, and that emit blue light. With the second light emitting element 10b and the third light emitting element 10c each having a peak emission wavelength longer than the near ultraviolet region, disadvantages of light of the near ultraviolet region (e.g. an adverse effect on a human body or on an irradiated object, degradation of the constituent members of the light emitting device that leads to great reduction in light emission efficiency of the light emitting device).

For the package 1 used in the light emitting device 200 and the light emitting device 300, a package similar to the package 1 of the light emitting device 100 can be used. In other words, for example, it is possible to have a depth of the recess 2 of the package 1, or a ratio between a depth of the recess 2 and a height of the light emitting element, etc. be the same as those in the light emitting device 100.

The light emitting device 200 comprises the second sealing member 40b that contains the second phosphor 7b having the peak emission wavelength of 580 nm or greater and 680 nm or less. The second sealing member 40b covers the second light emitting element 10b. With the light emitting device 200 shown in FIG. 4B, the second sealing member 40b in which the second phosphor 7b is contained in a resin material such as silicone resin. The second sealing member 40b is formed for example, by being disposed inside the recess 2 using the potting method, etc., and being solidified.

The second phosphor 7b is a red phosphor that absorbs the blue light emitted by the second light emitting element 10b, and that emits red light. For the second phosphor 7b, it is preferable to use an (Sr, Ca)AlSiN₃:Eu phosphor. The half band width of the (Sr, Ca) AlSiN₃:Eu phosphor in the light emission spectrum is 125 nm or less, so that color reproducibility of a display device that incorporates the light emitting device 200 as the light source can be improved. Further, the (Sr, Ca) AlSiN₃:Eu phosphor, for example, is a phosphor with less afterglow than a phosphor such as K₂SiF₆:Mn⁴⁺, etc., so that the possibility of occurrence of an after-image or the like in the display device may be reduced.

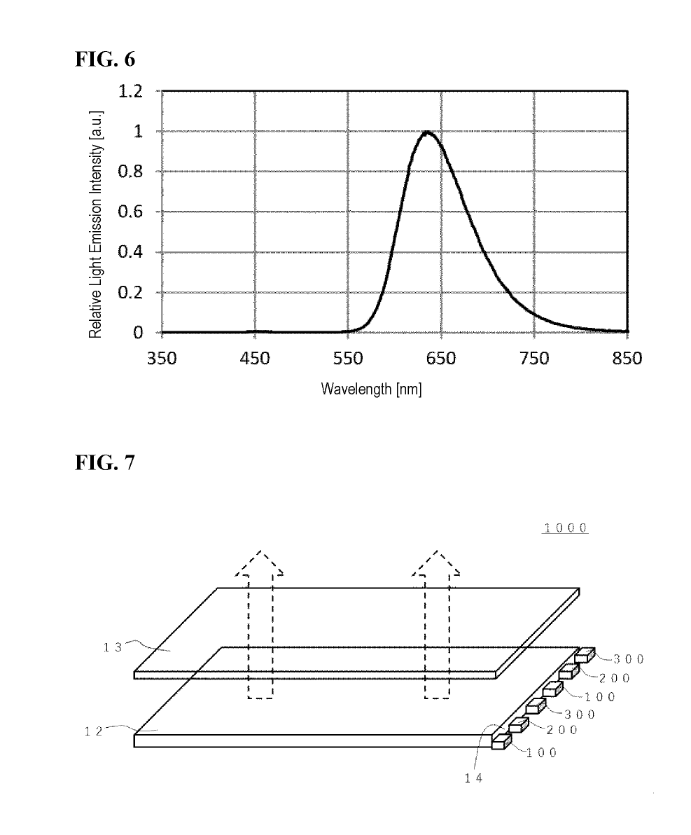

The content of the second phosphor 7b within the second sealing member 40b is 50 weight % or greater with respect to the total weight of the second sealing member 40b. With the second phosphor 7b contained at 50 weight % or greater in the second sealing member 400, it is possible to increase the ratio of the red component with respect to the blue component in the light emission spectrum of the light emitting device 200. FIG. 6 is a drawing showing the light emission spectrum of the light emitting device 200. The second light emitting element 10b and the second phosphor 7b are configured to have desired peak emission wavelengths such that, in the light emission spectrum of the light emitting device 200 shown in FIG. 6, the emission intensity at the peak emission wavelength of the second light emitting element 10b is 0.01 times or less of the emission Intensity at the peak emission wavelength of the second phosphor 7b. With this arrangement, the light emitting device 200 can be a light emitting device configured to emit red light while employing, the second light emitting element 10b, which is configured to emit blue light, as the light source.

The light emitting device 200 has excitation purity for red light, for example, of 85% or greater, preferably 90% or greater, and more preferably 95% or greater. With such an excitation purity, a display device in which the light emitting device 200 are incorporated as the light source can exhibit the color reproducibility improved in the red region.

The light emitting device 300 comprises a third sealing member 40c that does not contain a phosphor. The third sealing member 40c covers the third light emitting element 10c. The third sealing member 40c in the light emitting device 300 shown in FIG. 5B, is obtained by solidifying a resin material such as a silicone resin. The light emitting device 300 does not comprise phosphor, so that it is possible to obtain a light emitting device in which the third light emitting element 10c, which emits blue light, serves as the light source to emit blue light. In the light emitting device 300, an excitation purity of blue light is, for example, 85% or greater, preferably 90% or greater, and more preferably 95% or greater. With such an excitation purity, a display device in which the light emitting device 300 is incorporated as the light source can exhibit color reproducibility improved in the blue region.

The excitation purity of light emitted from the light emitting device 100 for the green light can be lower than, for example, the excitation purity of light emitted from the light emitting device 200 for the red light and the excitation purity of light emitted from the light emitting device 300 for the blue light.

Next, a display device 1000 that uses the light emitting device 100, the light emitting device 200, and the tight emitting device 300 will be explained. FIG. 7 is an exploded perspective view of the display device 1000 according to still another embodiment. The display device 1000 comprises: a light guiding plate 12; a light source device including at least one light emitting device 100 (first light emitting device 100), at least one light emitting device 200 (second light emitting device 200), and at least one light emitting device 300 (third light emitting device 300); and a light-transmissive substrate 13 disposed on the top surface of the light guiding plate 12.

The light guiding plate 12 includes a lateral surface 14 including a light-incident portion, and the at least one light emitting device 100, the at least one light emitting device 200, and the at least one light emitting device 300 are disposed facing the lateral surface 14 of the light guiding plate 12. In the display device 1000 shown in FIG. 7, the light emitting device 100 two light emitting devices 200, and two light emitting device 300 are arranged in a straight line. The display device of this disclosure is not limited to this. The number, arrangement, etc., of the light emitting devices can be changed according to the purpose or application.

The display device 1000, for example, is a so-called see through type display device, which can show, as well as the display image, the backside of the display device. The see-through type display device can realize a novel display that could not be realized with conventional display devices, and thus can have a good eye-catching effect.

In the display device 1000, with respect to the total value of luminous flux of all the light emitting, devices, the maximum luminous flux value is, for example, 50% or greater, preferably 60% or greater, and more preferably 65% or greater. With such a luminous flux value, it is possible to obtain a display device with a high brightness. Also, in the display device 1000, the light emitting device 100 including the first light emitting element 10a and, the first phosphor 7a with high excitation efficiency with respect to light emitted from the first light emitting element 10a are used, so that a display device having a higher brightness particularly in the green region compared to a display device that uses the green light emitting element as the light source can be obtained. While a light source comprising a plurality of green light emitting elements instead of the light emitting device 100 can be used for a display device with a higher brightness, in the light emitting device 100, adjustment of the concentration of the first phosphor 7a allows for adjusting chromaticity, luminous flux, or excitation purity of light emitted from the light emitting device easier than in a light source comprising a plurality of green light emitting elements instead of the light emitting device 100. Also, the greater the number of the green light emitting elements, the more complicated wirings at a substrate side, etc. may become, and thus designing of the display device may become difficult.

Also, the display device 1000 comprises the first light emitting device 100, the second light emitting device 200, and the third light emitting device 300 each of which including a similar blue light emitting element, which allows for facilitating, designing of the display device. Furthermore, driving the light emitting devices individually for each emission color allows the display device 1000 according to the present disclosure to easily reproduce a desired light. Accordingly, electrodes, wirings at a substrate side, and the like in each of the light emitting devices can be simplified compared to, for example, the display device including one or more light emitting devices each comprising elements for emitting red, green, and red (RGB) light as the light source of the display device.

Configurations of the display device according to one embodiment of the present invention can be preferably applied also to display devices other than the see-through type display device.

Member used in the light emitting device 100, etc., and the display device 1000 according to certain embodiments of the present invention will be described below in detail.

### Light Emitting Element

The first light emitting element 10a, the second light emitting element 10b, and the third light emitting element 10c function as a light source of the light emitting device, For the light emitting elements, light emitting diode elements or the like can be used, an. a nitride semiconductor that can emit light in the visible range (InₓAl_{y}Ga_{1-x-y}N, 0≤x, 0≤y, x+y≤1) can be preferably used.

The first light emitting element 10a, the second light emitting element 10b, and the third light emitting element 10c are light emitting elements that have the peak emission wavelength of 490 mn or greater and 570 or less, and are configured to emit blue light. For each light emitting element, a light emitting element having a half band width of 40 nm or less is preferably used, and alight emitting element having a half band width of 30 nm or less. With such light emitting elements, for example, if a blue component is present in light emission spectrum of the light emitting device 100 or the light emitting device 200, an integrated value of the blue component can be reduced, and possible to increase the purity of green or red. Also, in the light emitting device 300, a sharp emission peak of a blue light can be easily obtained. Thus, for example, when using the light emitting device 300 for the light source of the display device, it is possible to obtain a display device with good color reproducibility in the blue region.

Each of the light emitting device 100, the light emitting device 200, and the light emitting device 300 includes a single light emitting element having a substantially rectangular planar shape. The light emitting device of the present disclosure may alternatively have any other appropriate shape. In the light emitting device 100, etc., the planar shape of the light emitting element, the number of the light emitting element(s), and the arrangement of the light emitting elements, etc., can be changed according to the purpose or application.

### First Sealing Member, First Phosphor

The light emitting device 100 comprises the first sealing member 40a that contains the first phosphor 7a adapted to convert the wavelength of the light emitted from the first light emitting element 10a. The first phosphor 7a is a phosphor having a peak emission wavelength of 490 nm or greater and 570 nm or less. For the first sealing member 40a, for example, a resin material in which the first phosphor 7a is contained in a silicone resin or the like is used, and the first sealing member 40a is formed using printing, an electrophoretic deposition method, potting, a spray method, etc. Also, the first sealing member 40a, for example, is made of resin member, glass, ceramic, or the like in a sheet form or block form, and is formed by bonding a resin member, etc. using an adhesive agent, etc.

For the resin material to be a base material of the first sealing member 40a, a thermosetting resin, a thermoplastic resin, etc. can be used, and for example, a resin containing silicone resin, epoxy resin, acrylic resin, or a resin containing one or more of these can be used. Also, in the first sealing member 40a, in addition to the first phosphor 7a, light scattering particles such as of titanium oxide, silicon oxide, zirconium oxide, aluminum oxide, etc., may be disposed. The light scattering particles may have a crushed shape, a spherical shape, a hollow shape, a porous shape, or the like.

For the first phosphor 7a, for example, a phosphor such as (Ca, Sr, Ba)₈MgSi₄O₁₆ (F, Cl, Br)₂:Eu Si_{6-z}Al_{z}O_{z}N_{8-z}:Eu (0<z<4.2), Ba₃Si₆O₁₂N₂:Eu, or the like may be used. In particular, (Ca, Sr, Ba)₈MgSi₄O₁₆ (F, Cl, Br)₂:Eu phosphor can be preferably used.

The first sealing member 40a can comprise another phosphor in addition to the first phosphor 7a. Examples of such another phosphor include a phosphor such as (Ca, Sr, Ba)₅(PO₄)₃(Cl, Br):Eu, Si_{6-z}AlₓO_{z}N_{8-z}:Eu (0<z<4.2), (Sr, Ca Ba)₄Al₁₄O₂₅:En, (Ca, Sr, Ba)₈MgSi₄O₁₆ (F, Cl, Br)₂:Eu, (Y, Lu, Gd)₃(Al, Ga)₅O₁₂:Ce, Ca₃Sc₂Si₃O₁₂:Ce, and CaSc₂O₄:Ce.

### Second Sealing Member, Second Phosphor

In the second sealing member 40b, a resin material, light scattering particles, etc., similar to those used in the first sealing member 40a can be appropriately used. The second sealing member 40b contains the second phosphor 7b for converting the wavelength of light emitted from the second light emitting element 10b.

For the second phosphor 7b, for example, a phosphor such as (Sr, Ca)AlSiN₃:Eu, CaAlSiN₃:Eu, K₂SiF₆:Mn⁴⁺, or 3.5 MgO.0.5 MgF₂.GeO₂:Mn⁴⁺ can be used. In particular, (Sr, Ca)AlSiN₃:Eu phosphor can be preferably used.

### Third Sealing Member

In the third sealing member 40c, a resin material, light scattering particles, etc., similar to those used in the first sealing member 40a can be appropriately used. The third sealing member 40c does not contain a phosphor.

### Package

The light emitting device can comprise the package 1. The package 1 is a base on which the light emitting element is to be disposed. The package 1 has includes a base body and a plurality of leads (i.e., plurality of electrode parts). The package 1 can define the recess 2. Examples of a material used for the base body of the package 1 include, a ceramic of an aluminum oxide aluminum nitride, etc., a resin (for example, silicone resin, silicone modified resin, epoxy resin, epoxy modified resin, unsaturated polyester resin, phenol resin, polycarbonate resin, acrylic resin, trimethyl pentene resin, polynorbornene resin, or a hybrid resin of one or more of these resins, etc.), pulp, glass, or a composite material of these.

The outline of the package 1 has, for example, a quadrangular shape of 3.0 mm×1.4 mm, 2.5 mm×2.5 mm, 3.0 mm×3.0 mm, 4.0 mm×4.0 mm, or 4.5 mm×4.5 mm in a top view. The shape of the outline of the package 1 in the top view, is not limited to be a quadrangle, but may alternatively be another shape such as a polygon, elliptical shape, etc.

As an example, of the package 1, a package comprising a resin part 30 used in the light emitting device 100 in FIG. 1A etc., a first lead 51, and a second lead 52 can be preferably used. Such a structure allows for obtaining an inexpensive light emitting device with high heat dissipation performance. In the light emitting device 100 shown in FIG. 1A, etc., the first lead 51 and the second lead 52 do not extend outward of the resin part 30 at an outer lateral surface of the package 1, but the light emitting device according to the present embodiment is not limited to this. In other words, at an outer lateral surface of the package 1, the first lead 51 and the second lead 52 may extend outward of the resin part 30. With this arrangement, heat generated from the light emitting element can be efficiently dissipated to an outside.

### Resin Part

For a resin material to be a base material of the resin part 30, a thermosetting resin, thermoplastic resin, or the like may be used. More specifically, it is possible to use an epoxy resin compound, a silicone resin compound, a modified epoxy resin compound such as a silicone modified epoxy resin, a modified silicone resin compound such as an epoxy modified silicone resin, a cured article of a modified silicone resin compound, an unsaturated polyester resin, a saturated polyester resin, a polyimide resin compound, a modified polyimide resin compound, etc., or a resin such as polyphthalamide (PPA), polycarbonate resin, polyphenylene sulfide (PPS), liquid, crystal polymer (LCP), ABS resin, phenol resin, acrylic resin, or PBT resin. In particular, for the resin material of the resin part 30, a thermosetting resin of an epoxy resin composition or a silicone resin composition with good hut resistance and light resistance can be used.

The resin part 30 preferably contains a resin material to be the base material as described above, and a light reflective substance in the resin material. For the light reflective substance, a material that does not easily absorb light emitted from the light emitting element and has a refractive index greatly different from that of the resin material to be the base material. Examples of such a light reflective substance includes titanium oxide, zinc oxide, silicon oxide, zirconium oxide, aluminum oxide, aluminum nitride, etc.

### First Lead, Second Lead

The first lead 51 and the second lead 52 are electrically conductive, and function as electrodes for supplying electricity to the light emitting element. For a base member of each of the first lead 51 and the second had 52, for example, a metal such as copper, aluminum, gold, silver, iron, nickel, or alloys of these, phosphor bronze, or iron containing copper, can be used. These materials can be used in a single layer, or in a layered structure (a clad member, for example). In particular, for the base material, copper, which is inexpensive and having high heat dissipation, can be used.

The first lead 51 and the second lead 52 may include a metal layer on a surface of the base material. The metal layer, for example, can contain silver aluminum, nickel, palladium, rhodium, gold, cover, or alloys of these, etc. The metal layer can be disposed on all or some of the surfaces of the first lead 51 and the second lead 52. Also, the metal layer on an upper surface of each of the first and the second leads, and the metal layer on the lower surface thereof may be made of different materials. For example, the metal layer on the upper surface of each of the first and the second leads can be a metal layer comprising a plurality of layers including nickel layer and silver layer, and the metal layer on the lower surface of each of the first and the second leads can be a metal layer that does not include a nickel metal layer.

When a metal layer containing silver is formed on an outermost surface of the first lead 51 and/or an outermost surface of the second lead 52, a protective layer of silicon oxide, etc., on a surface of the metal layer containing silver. With this arrangement, discoloration of the metal layer containing silver due to the sulfur component, etc., in the atmosphere can be reduced. The protective layer can be formed by, for example, using a vacuum process such as sputtering, but it is also possible to use another known method.

The package 1 comprises at least two electrodes (for example, the first lead 51 and the second lead 52). The package 1 may comprise three or more electrodes; for example, the package 1 can comprise a third lead in addition to the first lead 51 and the second lead 52. The third lead may function as a heat dissipation member, and may also function as an electrode, similarly to the first lead 51, etc.

Each of the first lead 51, the second lead 52, and the third lead, and the like, (hereafter referred to as “a lead, part 5”) can have a groove in an upper surface or a lower surface thereof. With the lead part 5 having grooves, adhesion between the lead part 5 and the resin part 30 can be improved.

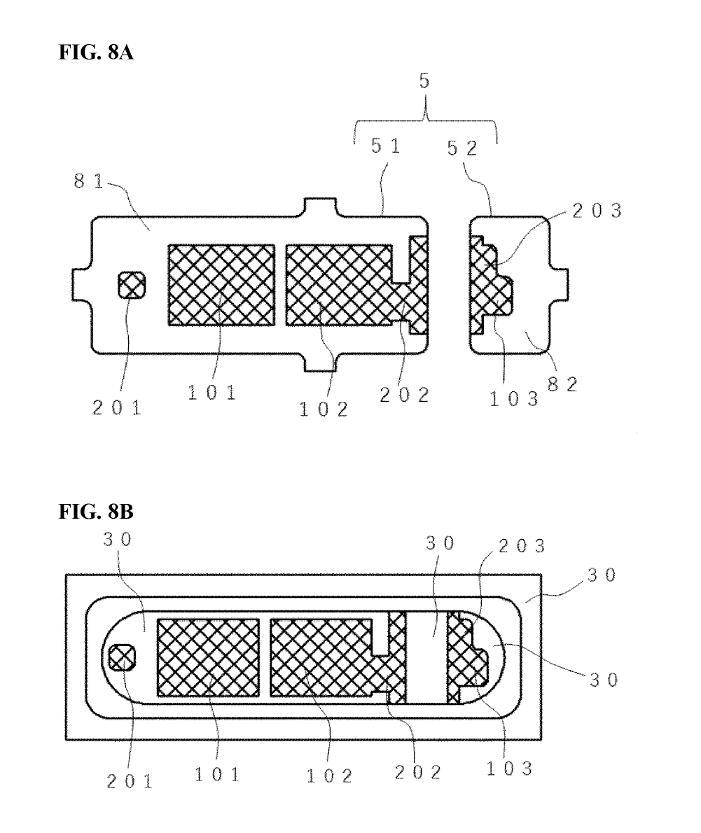

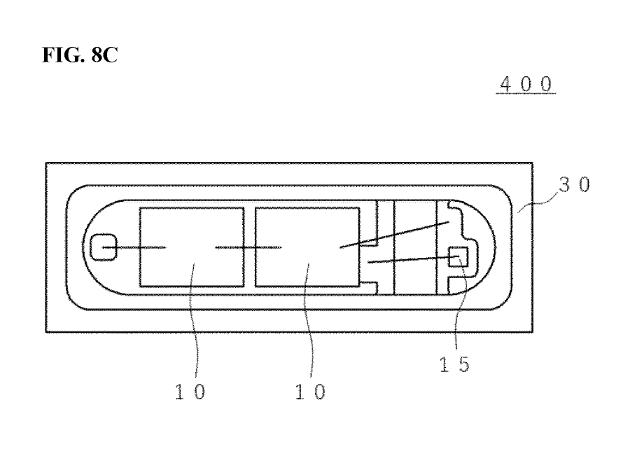

FIG. 8A is a schematic top view of the lead part 5 when grooves are formed on the top surface of the lead pan 5. FIG. 8B is a schematic top view showing an example of the package 1 using the lead part 5. FIG. 8C is a schematic top view showing an example of a light emitting device 400. Each of FIG. 8A and FIG. 8B shows the lead part 5 exposed on the bottom surface of the recess 2, in which regions with cross hatching indicate portions of the lead part 5 that have a smaller thickness, the lead part 5 has a first groove 81 on the upper surface of the first lead 51, and a second groove 82 on the upper surface of the second lead 52. Further, the upper surface of the first lead 51 includes a first element placing region 101 and a second element placing region 102, and a first wire connection region 201 and a second wire connection region 202. The upper surface of the second lead 52 includes a third element placing region 103 and a third wire connection region 203. Each of the first to third element placing regions 101 to 103 is a region on which a respective light emitting element, a protection element, or the like, is mounted, and each of the first to third wire connection regions 201 to 203 is a region to which one end portion of a wire extending from the light emitting element, the protection element, or the like are connected.

In the package 1 shown in FIG. 8B, the resin part 30 enters the first groove 81 and ate second groove 82. Accordingly, at the bottom surface off the recess 2, only a portion of the region including the element placing region and the wire connection region are exposed from the resin part 30. With this arrangement, even if oxygen, sulfur, etc., enters the recess 2 an area of the first lead 51 and the second lead 52 exposed to oxygen, sulfur, etc., can be reduced, and possibility of occurrence of a rapid decrease in the light reflectance of the package 1 can be reduced. Thus, the package 1 can efficiently extract light emitted from the light emitting element to outside over a long period.

The wire connection region on the first lead 51 or the second lead 52 can be continuous with corresponding element placing region on the same lead, in the top view. For example, in the package 1 shown in FIG. 8B, in the top view, the second element placing region 102 and the second wire connection region 202 are continuous on the upper surface of the first lead 51. Also, in the top view, the third element placing region 103 and the third wire connection region 203 are continuous on the upper surface of the second lead 52. With this arrangement, or example, if oxygen, sulfur, etc., enters the recess 2, the oxygen, sulfur, etc., concentrates mainly in the first to third wire connection regions 201 to 203, and it is possible to reduce the possibility of occurrence of breakage of the wires connected to the wire connection region.

The light emitting device 400 comprises, for example, two light emitting elements 10 for which the peak emission wavelength is 430 nm or greater and less than 490 nm, and one protection element 15. The light emitting device 400 is, for example, a white light emitting device that contains phosphor. For the phosphor, for example, Si₆₋ₓAl_{z}O_{z}N_{8-z}:Eu (0<z<4.2) phosphor and K₂SiF₆:Mn⁴⁺ phosphor may be used in combination. Each of these phosphors has a narrow half band width in the light emission spectrum, so that color reproducibility of the display device in which the light emitting device 400 is used as the light source can be improved. The light emitting device 400 can be a blue light emitting device that does not contain phosphor.

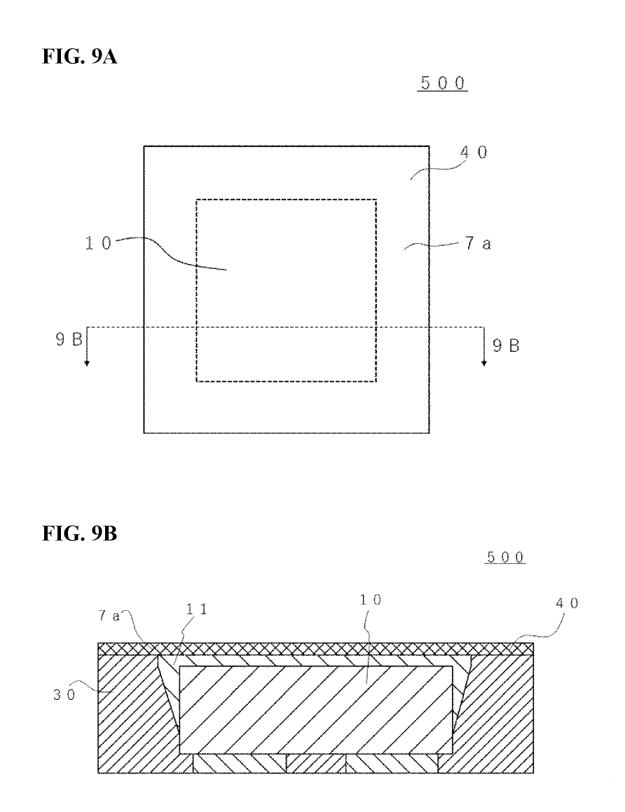

The light emitting device may not comprise the package 1. FIG. 9A is a schematic top view showing an example of a light emitting device 500 that does not comprise the package 1, and FIG. 9B is a schematic cross sectional view taken along a line 9B-9B in FIG. 9A. The light emitting device 500 comprises the light emitting element 10, the sealing member 40 disposed on the upper surface of the light emitting element 10, the light-transmissive layer 11 disposed on a lateral surface of the light emitting element 10, and the resin part 30 covering the outer surfaces of the light-transmissive layer 11. The sealing member 40 can contain the first phosphor 7a, for example.

The light-transmissive layer 11 covers at least lateral surfaces of the light emitting clement 10, and guides light emitted from the lateral surfaces of the light emitting element 10 toward the upper surface of the light emitting device 500. With the light-transmissive layer 11 disposed on the lateral surfaces of the light emitting element 10, of a light that have reached a lateral surface of the light emitting element 10, a ratio of a portion of the light reflected at the lateral surface and attenuated can be reduced. In the light emitting device 500 shown in FIG. 9B, the light-transmissive layer covers the tipper surface of the light emitting element 10 in addition to the lateral surfaces thereof. For a resin material to be used for a base material of the light-transmissive layer 11, a resin material as in examples of the resin material of the resin part 30 can be used, and in particular, a light-transmissive resin such as silicone resin, silicone modified resin, epoxy resin, or phenol resin can be preferably used. The light-transmissive layer 11 preferably has high light transmittance. In view of this, it is preferable that the light-transmissive layer 11 does not have a substance that reflects, absorbs, or scatters light.

The resin part 30 covers the outer surfaces of the light-transmissive layer 11 disposed on the lateral surfaces of the light emitting element 10, and a portion of each of the lateral surfaces of the light emitting element 10. A resin material for the resin part 30 can be preferably selected such that, for example, when difference between the thermal expansion coefficient of the light-transmissive layer 11 and the thermal expansion coefficient of the light emitting element 10 (hereinafter referred to as a “first thermal expansion coefficient difference ΔT30”) and difference between the thermal expansion coefficient of the resin part 30 and the thermal expansion coefficient of the light emitting element 10 (hereinafter referred to as a “second thermal expansion coefficient difference ΔT40”) are compared, ΔT40<ΔT30 are satisfied. Using such a material allows for preventing detachment of the light-transmissive layer 11 from each light emitting element.

The configurations of each light emitting device can also be suitably applied to other light emitting devices.

What is claimed is:

1. A light emitting device comprising:
a first light emitting element having a peak emission wavelength of 430 nm or greater and less than 490 nm; and
a first sealing member covering the first light emitting element, and containing a first phosphor having a peak emission wavelength of 490 nm or greater and 570 nm or less, with a content of the first phosphor is 50 weight % or greater with respect to a total weight of the first sealing member, wherein
a mixed color light in which light emitted from the first light emitting element and light emitted from the first phosphor are mixed has an excitation purity of 70% or greater on a 1931 CIE chromaticity diagram.

2. The light emitting device according to claim 1, wherein
in a light emission spectrum of the light emitting device, an emission intensity at the peak emission wavelength of the first light emitting element is 0.1 times or less of an emission intensity at the peak emission wavelength of the first phosphor.

3. The light emitting device according to claim 2, wherein
in the light emission spectrum of the light emitting device, the emission intensity at the peak emission wavelength of the first light emitting element is 0.01 times or more and 0.03 times or less of the emission intensity at the peak emission wavelength of the first phosphor.

4. The light emitting device according to claim 1, wherein
on the 1931 CIE chromaticity diagram, a chromaticity of light emitted from the light emitting device is positioned in an area surrounded by a first point, a second point, a third point, and a fourth point, and
the x, y coordinates of the first point are 0.236, 0.620, the x, y coordinates of the second point are 0.272, 0.700, the x, y coordinates of the third point are 0.292, 0.700 and the x, y coordinates the fourth point are 0.256, 0.620.

5. The light emitting device according to claim 1, wherein
the first phosphor has a composition represented by (Ca, Sr, Ba)₈MgSi₄O₁₆(F, Cl, Br)₂:Eu.

6. The light emitting device according to claim 1, further comprising
a package defining a recess, wherein
the first light emitting element is disposed on a bottom surface of the recess,
the first sealing member covers the first light emitting element in the recess, and
a depth of the recess is ⅔ or more of a height of the package.

7. A light source device comprising:
the light emitting device according to claim 1 serving as a first light emitting device;
a second light emitting device including
a second light emitting element having a peak emission wavelength of 430 nm or greater and less than 490 nm, and
a second sealing member covering the second light emitting element, and containing a second phosphor having a peak emission wavelength of 580 nm or greater and 680 nm or less, and
a third light emitting device including
a third light emitting element having a peak emission wavelength of 430 nm or greater and less than 490 nm, and
a third sealing member covering the third light emitting element, wherein the third sealing member does not contain phosphor.

8. The light source device according to claim 7, wherein
a content of the second phosphor is 50 weight % or greater with respect to a total weight of the second sealing member.

9. The light source device according to claim 7, wherein
the excitation purity of the first light emitting device is lower than an excitation purity of the second light emitting device or an excitation purity of the third light emitting device.

10. The light source device according to claim 7, wherein
in a light emission spectrum of light emitted from the second light emitting device, an emission intensity at the peak emission wavelength of the second light emitting element is 0.01 times or less of an emission intensity at the peak emission wavelength of the second phosphor.

11. The light source device according to claim 7, wherein
the second phosphor has a composition represented by (Sr, Ca)AlSiN₃:Eu.

12. A display device comprising:
the light source device according to claim 7;
a light-transmissive light guiding plate including a lateral surface having a light-incident portion; and
a light-transmissive substrate disposed on an upper surface of the light guiding plate, wherein
the light source device is disposed facing the lateral surface of the light guiding plate having the light-incident portion.
